(19) United States
(12) Patent Application Publication
(10) Pub. No.: US 2012/0305935 A1
(43) Pub. Date: Dec. 6, 2012

(54) APPARATUS FOR PRODUCING METAL CHLORIDE GAS AND METHOD FOR PRODUCING METAL CHLORIDE GAS, AND APPARATUS FOR HYDRIDE VAPOR PHASE EPITAXY, NITRIDE SEMICONDUCTOR WAFER, NITRIDE SEMICONDUCTOR DEVICE, WAFER FOR NITRIDE SEMICONDUCTOR LIGHT EMITTING DIODE, METHOD FOR MANUFACTURING NITRIDE SEMICONDUCTOR FREESTANIDNG SUBSTRATE AND NITRIDE SEMICONDUCTOR CRYSTAL

(75) Inventor: Hajime FUJIKURA, Mito-shi (JP)

(73) Assignee: HITACHI CABLE, LTD., Tokyo (JP)

(21) Appl. No.: 13/483,191

(22) Filed: May 30, 2012

(30) Foreign Application Priority Data
May 31, 2011 (JP) 2011-121737

(51) Int. Cl. C01G 15/00; C01B 9/02; H01L 21/20; C30B 25/14; H01L 33/32; B01J 19/00; H01B 1/06

(52) U.S. Cl. 257/76; 422/129; 423/491; 252/521.5; 118/715; 438/478; 257/E33.025; 257/E21.09

(57) ABSTRACT

There is provided an apparatus for producing metal chloride gas, comprising: a source vessel configured to store a metal source; a gas supply port configured to supply chlorine-containing gas into the source vessel; a gas exhaust port configured to discharge metal chloride-containing gas containing metal chloride gas produced by a reaction between the chlorine-containing gas and the metal source, to outside of the source vessel; and a partition plate configured to form a gas passage continued to the gas exhaust port from the gas supply port by dividing a space in an upper part of the metal source in the source vessel, wherein the gas passage is formed in one route from the gas supply port to the gas exhaust port, with a horizontal passage width of the gas passage set to 5 cm or less, with bent portions provided on the gas passage.

The present application is based on Japanese Patent Applications, No. 2011-121737 filed on May 31, 2011, the entire contents of which are hereby incorporated by reference.

### TECHNICAL FIELD

The present invention relates to an apparatus for producing metal chloride gas and a method for producing the metal chloride gas using the same and an apparatus for hydride vapor phase epitaxy, and a nitride semiconductor wafer, a nitride semiconductor device, a wafer for nitride semiconductor light emitting diode, a method for manufacturing a nitride semiconductor freestanding substrate and a nitride semiconductor crystal.

### DESCRIPTION OF RELATED ART

A nitride compound semiconductor such as GaN, AlGaN, and GaInN attracts attention as a material of a light emitting element capable of emitting light from red color to ultraviolet. As one of the crystal growth methods of these nitride semiconductor materials, Hydride Vapor Phase Epitaxy (HVPE method) using metal chloride gas and ammonia (NH₃) as sources (raw materials), can be given. The HVPE method has a characteristic of obtaining a considerably faster growth speed of 10 μm/hr or more or 100 μm/hr or more, compared with a typical growth speed of about 1 μm/hr of other crystal growth method such as Metal Organic Vapor Phase Epitaxy (MOVPE method) or Molecular Beam Epitaxy (MBE method). Therefore, the HVPE method is frequently used for manufacturing a GaN freestanding substrate or an AlN freestanding substrate (for example, see patent document 1)

Further, light emitting diode (LED) composed of a nitride semiconductor is usually formed on a sapphire substrate, and in a case of the crystal growth of the nitride semiconductor, a buffer layer is formed on a surface of a substrate, then a thick GaN layer of <10 μm including a n-type clad layer thereon is grown, and a light emitting layer of InGaN/GaN multiple quantum well (several 100 nm thickness in total) and a p-type clad layer (with a thickness of 20 to 500 nm) are further grown thereon in this order. The GaN layer on a lower side of the light emitting layer is formed thick, for improving crystallinity of GaN on the sapphire substrate. Thereafter, electrode formation, etc., is carried out, and an LED element structure as shown in FIG. 15 is finally formed. When the nitride semiconductor crystal for LED is grown on the sapphire substrate by MOVPE, time of about six hours is required typically for a crystal growth process, and about half of this time is the time required for growing the GaN layer on the lower side of the light emitting layer.

A portion on the sapphire substrate where a thick GaN film is grown, is called a template, and if the HVPE method can be used, which realizes a considerably high growth speed for growing the GaN thick film of this template, the growth time can be significantly shortened, and a manufacturing cost of the LED wafer can be dramatically reduced.

However, the HVPE method involves problems that the growth speed is changed every time the GaN layer grows, and a sudden On/Off control of a source gas is difficult. These problems are caused by a structure itself of a HVPE apparatus, and therefore a complete solution has not been obtained heretofore, thus posing a problem of the nitride semiconductor freestanding substrate in terms of manufacture or in terms of manufacture of the template.

FIG. 19 shows a typical structure of the HVPE apparatus. The HVPE apparatus includes a reaction vessel 20 that performs a crystal growth of the nitride semiconductor, and a source vessel (metal storage vessel) 100 of an apparatus for producing metal chloride gas such as GaCl is provided inside of the reaction vessel 20. Metal source M of group III such as Ga, In, Al is stored in the source vessel 100 heated by a source section heater 21, and a chlorine-based gas supply tube 4 for supplying chlorine-containing gas G1 containing chlorine-based gas such as HCl is connected to the source vessel 100. Metal chloride gas is produced in the reaction vessel 100 by a reaction between the metal source M and the chlorine-based gas supplied into the source vessel 100 from the chlorine-based gas supply tube 4. Metal chloride-containing gas G2 containing produced metal chloride gas is discharged from the metal chloride gas exhaust tube 5 connected to the source vessel 100, and is sent to a substrate (wafer) 25 installed in a growth section heated by a growth section heater 22 in the reaction vessel 20. The reaction vessel 20 is further provided with a NH₃ gas supply tube 23 for supplying NH₃-containing gas G3 containing ammonia gas (NH₃ gas) of group V source, and a doping source gas supply tube 24 for supplying doping source-containing gas G4 containing doping source gas. Group III nitride semiconductor crystal grows on the substrate 25 by a reaction between the metal chloride gas from the metal chloride gas exhaust tube 5 sent to the substrate 25, and the NH₃ gas sent from the NH₃ gas supply tube 23.

A boat-shaped source vessel 100 is generally used to enlarge a contact area contacted with the chlorine-based gas, by widening a surface area (or liquid surface) of the metal source M, to thereby covert all supplied chlorine-based gas to the metal chloride gas. Meanwhile, a simple thin tube is generally used for the NH₃ gas supply tube 23 and the doping gas supply tube 24.

Patent document 2 describes a solution for solving the problem of the HVPE method such that the growth speed is changed if the growth is repeated. According to patent document 2, in order to keep approximately a constant distance between the chlorine-based gas and the metal source in a liquid state stored in the source vessel of the HVPE apparatus, a setting angle, etc., of the source vessel can be adjusted corresponding to an amount of a metal source stored in the source vessel. Further, according to patent document 2, in order to keep approximately a fixed shape of a space of inside of the source vessel through which the gas passes, the setting angle, etc., of a specifically shaped source vessel can be adjusted corresponding to an amount of the metal source stored in the source vessel.
Patent document 1: Patent Publication No. 3886341
Patent document 2: Japanese Patent Laid Open Publication No. 2006-120857

Concentration of the metal chloride gas contained in the gas supplied to the growth section of the reaction vessel, is determined by a flow rate of the chlorine-based gas supplied into the reaction vessel, a flowing manner (such as a route and a flow velocity), and a temperature inside of the source vessel, etc.

For example, in a case that the metal source is consumed in the growth of a certain nitride semiconductor, volume of the space in an upper part of the metal source in the source vessel becomes larger in the next growth than the volume of the previous growth. In the source vessel of the apparatus for producing metal chloride gas used for a conventional HVPE apparatus, most of the case is that production efficiency of the metal chloride gas depends on the volume of the space in the upper part of the metal source in the source vessel. Therefore, the volume becomes larger every time the growth is repeated and producing amount of the metal chloride gas is reduced, resulting in a deterioration of the growth speed in the growth section of the reaction vessel. This is a factor that the growth speed is not stable in the HVPE method.

Instability of the growth speed involves an extreme difficulty in the manufacture of the nitride semiconductor freestanding substrate that consumes a large volume of metal in one growth. Namely, the growth speed is gradually decreased during growth of the nitride semiconductor, being the freestanding substrate, thus making it difficult to obtain a desired film thickness. Further, even in a case that a so-called template is manufactured, in which a GaN thick film is grown on the sapphire substrate for example, the instability of the growth speed brings about difficulty. In this case, metal consumption is small in one growth, and therefore the growth speed is not changed in the growth of several number times. However, in a mass production of the templates in which several hundred to several thousand times of growths are repeated, the growth speed is decreased unnoticeably, resulting in a template not satisfying a specified GaN film thickness, or deteriorating the characteristics (mainly dislocation density or sheet resistance) of the template, with a decrease of the growth speed.

Further, a passage of the gas in the source vessel has a certain degree of area and volume. Therefore, gas concentration shows a behavior of only a gradual change inside of the source vessel even if the concentration of the chlorine-based gas introduced into the source vessel is changed, and also shows gradual change of the metal chloride gas discharged from the source vessel and supplied to the growth section after elapse of several ten seconds to several minutes (transition time). Therefore, in the conventional HVPE method, the growth can't be started or stopped, or the growth speed can't be suddenly changed, or a steep heterointerface can't be formed.

A case of growing the GaN film on the sapphire substrate by HVPE method and forming the template by HVPE method, will be considered as an example. In this case, an uppermost layer of the GaN film is n-type GaN, and this is a state that the GaN layer is grown while being doped in a final stage of the growth, namely this is a state that all of the HCl gas, NH₃ gas, and doping source are supplied together with carrier gas (such as hydrogen and nitrogen). From these states, end of the growth of GaN will be considered by stopping source supply to a group III line for supplying HCl gas and a doping line for supplying doping source, and using carrier gas only. If the supply of the source excluding ammonia is stopped, the concentration of the doping source supplied to the surface of the substrate becomes zero within 1 second. However, supply of GaCl gas is not stopped immediately and the concentration thereof is gradually reduced, and becomes zero after elapse of the transition time of several ten seconds to several minutes. Namely, actually the supply of the doping source only is stopped at a point when the growth is desired to be stopped, and the GaN layer with a low carrier concentration close to an undoped state, is formed on the surface of the template.

Generally a thin tube (with a diameter of 6 mm for ¼ tube) is used for a doping line, and therefore passing time of the gas from an upstream end to the substrate (wafer) is about 1 second. Meanwhile, in a case of the group III line, a large volume of GaCl gas remains in the space in the source vessel at a point when the growth is desired to be stopped, and the supply of GaCl is not completely stopped and the growth of GaN is continued until all of the GaCl gas is expelled, thus forming the aforementioned state.

Of course, the time required for completely stopping the supply of GaCl to the substrate from the source supply can be shortened to a certain degree by making the source vessel small. However, this case involves a demerit of reducing the production efficiency of GaCl due to reduced contact area between HCl and the surface of Ga metal, and a demerit of increasing a frequency of supplying Ga due to reduced amount of Ga to be stored, which can't be a practical solution. As a dimension of the practical source vessel, 10 cm×10 cm or more is preferable as a surface area of Ga melt. However, in this case, the transition time of GaCl concentration is about 1 minute or more in most cases at present.

If the aforementioned low carrier concentration layer is formed on the surface of the template, and when the LED structure is formed by growing a light emitting layer and a p-type layer thereon by the MOVPE method, etc., an unintended low carrier layer is included under the light emitting layer. The LED element of a normal structure as shown in FIG. 15 is provided with an electrode (n-side electrode) 38 for electric connection to the n-type layer, in a part removed by etching from the surface of a semiconductor layer to light emitting layer 35 and n-type layer 34 (or n-type GaN layer on an upper layer of GaN layer 32). When processing is applied to the wafer for LED including the template formed by HVPE method to thereby manufacture the LED element, an electrical barrier is formed between the n-side electrode and the low carrier concentration GaN by coincidence of a depth of the etching and the depth of the low carrier concentration layer, and a drive voltage of LED exceeds a practical value (typically, 3.6V or less as a voltage during power supply of 20 mA).

Therefore, in a case that the LED element is manufactured by applying processing to the wafer for LED using the template formed by the conventional HVPE method, yielding rate of the LED element is decreased in terms of the drive voltage, if there is no control of more precise etching depth than a case of manufacturing the LED element from the wafer for LED entirely manufactured by the MOVPE method. However, in order to precisely control the etching depth, a counter measure is required such as performing preliminary experiment before etching or slowing down an etching speed, which involves an increase of a process cost, and therefore there is no meaning in using HVPE for reducing the cost.

Further, even in a case that not only a template portion but also the InGaN light emitting layer and the p-type layer thereon are grown, the source can't be switched suddenly, and a steep heterointerface can't be formed. Therefore, at present, the characteristic of the LED manufactured using HVPE is more deteriorated than LED manufactured using MOVPE.

### SUMMARY OF THE INVENTION

An object of the present invention is to provide an apparatus for producing metal chloride gas and a method for producing the metal chloride gas, capable of improving stability of a concentration of the metal chloride gas and improving response efficiency for a change of concentration of the metal chloride gas, and further provide a hydride vapor phase epitaxy apparatus using an apparatus for producing metal chloride gas and a method for manufacturing a nitride semiconductor freestanding substrate, and a nitride semiconductor wafer, a nitride semiconductor device, a wafer for a nitride semiconductor light emitting diode, and a nitride semiconductor crystal.

According to a first aspect of the present invention, there is provided an apparatus for producing metal chloride gas, comprising:

a source vessel configured to store a metal source;

a gas supply port provided in the source vessel, and configured to supply chlorine-containing gas containing chlorine-based gas into the source vessel;

a gas exhaust port provided in the source vessel and configured to discharge metal chloride-containing gas containing metal chloride gas produced by a reaction between the chlorine-based gas contained in the chlorine-containing gas and the metal source, to outside of the source vessel; and

a partition plate configured to form a gas passage continued to the gas exhaust port from the gas supply port by dividing a space in an upper part of the metal source in the source vessel,

wherein the gas passage is formed in one route from the gas supply port to the gas exhaust port, with a horizontal passage width of the gas passage set to 5 cm or less, with bent portions provided on the gas passage.

### BRIEF DESCRIPTION OF THE DRAWINGS

FIG. 1 is a view showing an apparatus for producing metal chloride gas according to an embodiment of the present invention, wherein FIG. 1A is a cross-sectional view, and FIG. 1B is a side cross-sectional view.

FIG. 2 is a schematic block diagram of a HVPE apparatus according to an embodiment of the present invention using the apparatus for producing metal chloride gas of FIG. 1.

FIG. 3 is a horizontal cross-sectional view showing each kind of source vessel examined by an example.

FIG. 4 is a side cross-sectional view of the source vessel of FIG. 3B.

FIG. 5 is a graph showing a changing state of GaCl concentration by presence/absence of a partition plate in the source vessel.

FIG. 6 is a graph showing a relation between Ga depth and a delay time in each source vessel of FIG. 3.

FIG. 7 is a graph showing a relation between the Ga depth and a transition time in each source vessel of FIG. 3.

FIG. 8 is a graph showing a relation between the Ga depth and the GaCl concentration during stable time in each source vessel.

FIG. 9 is a graph showing a relation between a width of a gas passage and the delay time in each kind of source vessel having a partition plate.

FIG. 10 is a graph showing a relation between the width of the gas passage and the transition time in each kind of source vessel having the partition plate.

FIG. 11 is a graph showing a relation between the width of the gas passage and the GaCl concentration during stable time in each kind of source vessel having the partition plate.

FIG. 12 is a graph showing a Si concentration distribution on a surface portion of a GaN film on the surface of a template, when the template is manufactured by a HVPE apparatus using the source vessel having the partition plate and the source vessel without the partition plate respectively.

FIG. 13 is a graph showing a relation between the width of the passage in the source vessel and a thickness of a low Si concentration layer of the template, when the template is manufactured by the HVPE apparatus using each kind of source vessel having the partition plate.

FIG. 14 is a graph showing a relation between the width of the passage in the source vessel and a yield rate of LED, when the template is manufactured by the HVPE apparatus using each kind of source vessel having the partition plate, and the LED is fabricated on the template.

FIG. 15 is a cross-sectional view showing an example of an LED element, being a nitride semiconductor device, fabricated on the template using the template manufactured by HVPE method.

FIG. 16 is a cross-sectional view showing an apparatus for producing metal chloride gas according to other example of the present invention.

FIG. 17 is a cross-sectional view showing the apparatus for producing metal chloride gas according to other example of the present invention.

FIG. 18 shows a Schottky barrier diode, being an example of a nitride semiconductor device according to the present invention, wherein FIG. 18A is a cross-sectional view, and FIG. 18B is a perspective view.

FIG. 19 is a schematic block diagram showing the HVPE apparatus using a conventional apparatus for producing metal chloride gas.

### DETAILED DESCRIPTION OF THE INVENTION

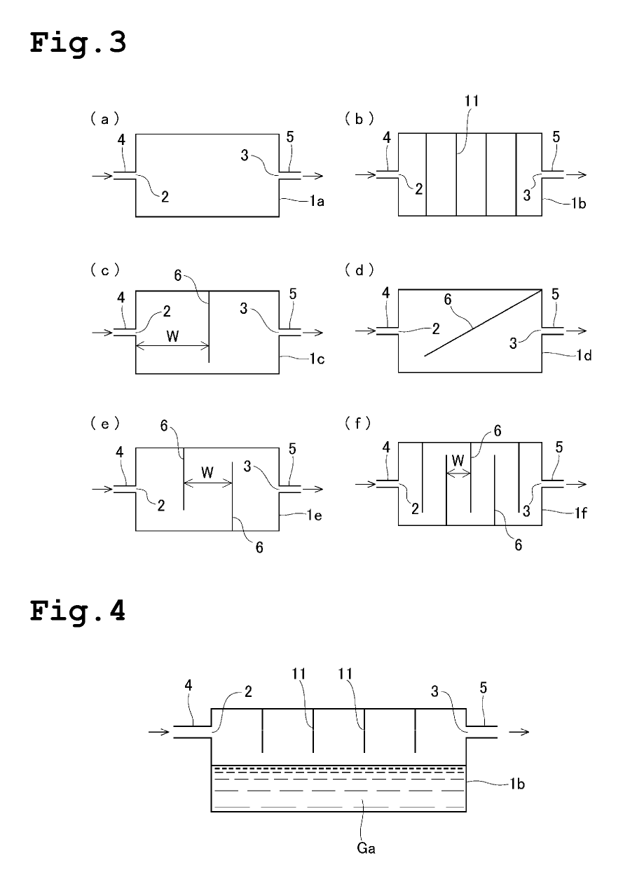

As a result of strenuous efforts by inventors of the present invention to solve the above-described problems, it is found that when there is a wide space in a source vessel to enable gas to relatively freely diffuse and flow in this space like a conventional source vessel (source vessel as shown in FIG. 3A of an example as will be described later), a phenomenon such that concentration of metal chloride gas becomes unstable, thus increasing a transition time (time required for gradually changing the concentration of the metal chloride gas to be fixed) appears remarkably. Therefore, in order to improve the aforementioned phenomenon, an apparatus for producing metal chloride gas according to the present invention realizes as follows. Namely, a gas passage is formed by dividing inside of a source vessel by partition plates, then the partitioned gas passage is formed in one route with almost no branch up to a gas exhaust port from a gas supply port, with a horizontal passage width of the gas passage set to 5 cm or less, and bent portions are provided to the gas passage, thus stabilizing the concentration of the metal chloride gas, and shortening a transition time to a degree allowable for device application.

Explanation will be given hereafter for an apparatus for producing metal chloride gas and a method for producing the metal chloride gas and an apparatus for hydride vapor phase epitaxy, and a nitride semiconductor wafer, a nitride semiconductor device, and a method for manufacturing a nitride semiconductor freestanding substrate.

### (An Apparatus for Producing Metal Chloride Gas)

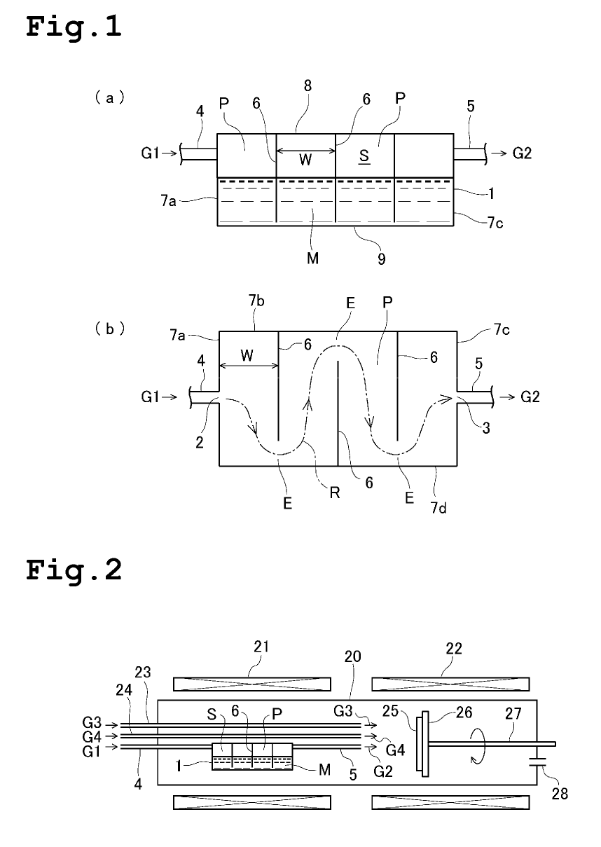

FIG. 1 shows an apparatus for producing metal chloride gas according to an embodiment of the present invention. FIG. 1A is a cross-sectional view, and FIG. 1B is a side-sectional view.

As shown in FIG. 1, the apparatus for producing metal chloride gas according to this embodiment, includes a source vessel (metal storage chamber) 1 storing metal source M of group III such as Ga, In, and Al. The metal source M may be in a liquid state or in a solid state. For example, when the temperature of the inside of the source vessel 1 is in the vicinity of 800° C., Ga, In, and Al are all set in a liquid state, however when the temperature is in the vicinity of 500° C., Al is remained in a solid state. Note that FIG. 1 shows a case that the metal source M is in the liquid state. The source vessel of this embodiment is made of quartz, and is a rectangular paralleletubed vessel. A heater (not shown) is provided outside of the source vessel 1, for melting or heating the metal source in the source vessel 1 by heating the source vessel 1 to a high temperature. A gas supply port 2 is formed on a side wall 7a, which is one of the opposed pair of side walls 7a 7c of the source vessel 1, for supplying chlorine-containing gas G1 containing chlorine-based gas (such as HCl, Cl₂) into the source vessel 1, and a gas exhaust port 3 is formed on the other side wall 7c for discharging metal chloride-containing gas G2 containing metal chloride gas (such as GaCl, InCl, AlCl₂) produced in the source vessel 1 to outside of the source vessel 1. A chlorine-based gas supply tube 4 is connected to the gas supply port 2, and a metal chloride gas exhaust tube 5 is connected to the gas exhaust port 3.

A partition plate 6 forming a gas passage P by dividing a space S in an upper part of the metal source M, is provided inside of the source vessel 1. The partition plate 6 of this embodiment is made of quartz and formed into a flat plate shape, and as shown in FIG. 1A, is formed in such a manner as being extended to the vicinity of a bottom wall 9 from a ceiling wall 8 of the source vessel 1. Not only the space S in the upper part of the metal source M, but also the metal source M stored in the source vessel 1, is set in a state divided or partitioned by the partition plate 6. Further, as shown in FIG. 1B, in the source vessel 1 of this embodiment, three partition plates 6 are provided in parallel to the side walls 7a, 7c on which the gas supply port 2 and the gas exhaust port 3 are formed, and at equal intervals between the gas supply port 2 and the gas exhaust port 3, and a horizontal passage width W of the gas passage P is set to 5 cm or less. Out of three partition plates 6, two partition plates 6 on the gas supply port 2 side and the gas exhaust port 3 side are extended to the side wall 7d from the side wall 7b, and one partition plate 6 in the center is extended to the side wall 7b from the side wall 7d, between the pair of side walls 7b, 7d where the gas supply port 2 and the gas exhaust port 3 are not formed. Thus, the gas passage P is formed in the source vessel 1 in such a manner as meandering from the gas supply port 2 to the gas exhaust port 3 by three partition plates 6 alternately extended from the side walls 7b, 7d, in a direction from the gas supply port 2 to the gas exhaust port 3, and a route R having no branch for flowing the gas, is formed along the gas passage P. Further, bent portions E of the gas passage P are formed at three places on the gas passage P between the partition plate 6 and the side wall 7b or the side wall 7d, on the gas passage P partitioned by the partition plate 6.

In a source vessel of a conventional structure as shown in FIG. 3A having no partition plate 6 in the source vessel 1 of the aforementioned embodiment, the chlorine-containing gas is diffused widely in the source vessel, and the metal chloride-containing gas containing metal chloride gas produced by being brought into contact with the metal source in the source vessel, is converged in the gas exhaust port and is discharged. In this case, there are lots of stagnating parts or stagnating regions in the source vessel, and production efficiency of the metal chloride gas is low, then the concentration of the metal chloride gas is largely decreased with reduction of the metal source, and the concentration of the metal chloride gas is not stable. Further, time (transition time) is required for entirely expelling the gas such as metal chloride gas present in the source vessel at a certain time point. Therefore, it is impossible to cope with a sudden change of the concentration of the metal chloride gas.

Meanwhile, in the source vessel 1 of the aforementioned embodiment, the gas passage P that continues to the gas exhaust port 3 from the gas supply port 2 is formed in the source vessel 1, and the gas supplied into the source vessel 1 flows through the route R limited to one route from the gas supply port 2 to the gas exhaust port 3. Therefore, there are not many stagnating parts or stagnating regions of the gas in the source vessel 1, and the chlorine-containing gas supplied from the gas supply port 2, is effectively brought into contact with the surface of the metal source M of approximately an entire area of the source vessel 1 while flowing through the gas passage P. Therefore, high production efficiency and conversion efficiency of the metal chloride gas can be obtained, and decrease of the concentration of the metal chloride gas can be suppressed even if the metal source M is reduced, and the concentration of the metal chloride gas can be stable. Further, since the gas passage P is thin and long with a horizontal passage width W of 5 cm or less, the gas present in the source vessel 1 can be efficiently expelled in a short period of time, and the transition time of the change of concentration of the metal chloride gas can be greatly shortened, and high production efficiency and conversion efficiency of the metal chloride gas can be obtained. Further, since the bent portions E are formed on the gas passage P, a large disturbance of a gas flow is generated in the bent portions E of the gas passage P, and therefore a reaction between the chlorine-based gas and the metal source M is promoted, and the production efficiency and the conversion efficiency of the metal chloride gas can be improved, and stability of the concentration of the metal chloride gas can be improved even if the metal source is reduced. The interval (width) between the partition plate 6 and the side walls 7b, 7d in the bent portions E is also preferably set to 5 cm or less similarly to the passage width W. Note that in the embodiment shown in FIG. 1, the interval (width) between the partition plate 6 and the side walls 7b, 7d is set to be narrower than the passage width W.

In the source vessel 1 of the apparatus for producing metal chloride gas, bent portion E is provided at least in one place in the middle of the gas passage P. However, the bent portions E are preferably provided in three places or more on the gas passage P.

Further, the source vessel 1 preferably has an area of 10 cm×10 cm. The area in this case is the area of a metal containing part in the source vessel 1 in which the metal source M is stored (area of a liquid surface in a case that the metal source M is in a liquid state). If the area of the source vessel 1 is smaller than 10 cm×10 cm, a contact area of the chlorine gas and the liquid metal source M is reduced, thus decreasing the production efficiency and the conversion efficiency of the metal chloride gas, and therefore the metal source needs to be frequently replenished. Even if the source vessel 1 of this embodiment has an area of 10 cm×10 cm or more, the transition time of the change of concentration of the metal chloride gas can be shortened to a sufficiently allowable degree.

Note that as shown in FIG. 1A, although the partition plate 6 of this embodiment reaches the vicinity of the bottom wall 9 from the ceiling wall 8 of the source vessel 1, it is not connected to the bottom wall 9. This is because if the partition plate 6 is continued and connected to the bottom wall 9 from the ceiling wall 8 of the source vessel 1, there is a risk of damaging the source vessel 1 by a stress generated by heating by the heater, etc. However, if a countermeasure for preventing the damage of the source vessel 1 is applied thereto, the partition plate 6 may be provided in a state of being continued and connected to the bottom wall 9 from the ceiling wall 8 of the source vessel 1.

### (A Method for Producing Metal Chloride Gas)

A method for producing metal chloride gas according to an embodiment of the present invention is the method using the apparatus for producing metal chloride gas according to the present invention represented by the aforementioned embodiment, and setting a residence time of the gas flowing through the gas passage P from the gas supply port 2 to the gas exhaust port 3 of the source vessel 1 is set to 5 seconds or more. Wherein, the residence time of the gas means a theoretical transit time of gas calculated from a volume of the space S in the upper part of the metal source M in the source vessel 1, the flow rate of the gas supplied into the source vessel 1 from the gas supply port 2, and the temperature in the source vessel 1.

If the residence time of the gas flowing through the gas passage P is set to 5 seconds or more, the decrease of the concentration of metal chloride gas can be suppressed during stable time (maximum concentration time) when the concentration of the metal chloride gas is fixed, after supply of the chlorine-based gas is started.

Any one of Ga, In, and Al is preferable as the liquid metal source M contained in the source vessel 1.

In the method for producing metal chloride gas, in a case of using Ga as the metal source M, preferably the temperature of the source vessel 1 is set to 700 to 950° C., and HCl-containing gas is introduced from the gas supply port 2, and GaCl-containing gas is produced from the gas exhaust port 3.

In the method for producing metal chloride gas, in a case of using In as the metal source M, preferably the temperature of the source vessel 1 is set to 300 to 800° C., and the HCl-containing gas is introduced from the gas supply port 2, and InCl-containing gas is produced from the gas exhaust port 3. Also, in a case of using In as the metal source M, the gas introduced from the gas supply port 2 may be Cl₂-containing gas. In this case, preferably the temperature of the source vessel 1 is set to 300 to 800° C., to thereby produce InCl₃-containing gas.

In the method for producing metal chloride gas, in a case of using Al as the metal source M, preferably the temperature of the source vessel 1 is set to 400 to 700° C., and HCl-containing gas is introduced from the gas exhaust port 3, and AlCl₃-containing gas is produced from the gas exhaust port 3. In a case of using Al as the metal source M, Al in the source vessel 1 is not in a liquid state but in a solid state in some cases.

The HCl-containing gas may contain hydrogen in addition to HCl. Further, the HCl-containing gas may contain inert gas in addition to HCl, and the inert gas may be any one of nitrogen, argon, and helium, or may be a mixed gas of them.

### (A Hydride Vapor Phase Epitaxy Apparatus)

FIG. 2 shows a hydride vapor phase epitaxy apparatus according to an embodiment of the present invention. The hydride vapor phase epitaxy apparatus of this embodiment includes the apparatus for producing metal chloride gas according to this embodiment.

As shown in FIG. 2, the hydride vapor phase epitaxy apparatus includes a reaction vessel 20 that carries out crystal growth of a nitride semiconductor. The reaction vessel 20 includes a source section provided with the source vessel 1 of the apparatus for producing metal chloride gas, and a growth section provided with a substrate 25 on which the source gas such as metal chloride gas is supplied from the source section and crystal growth of the nitride semiconductor is carried out. A source section heater 21 is provided on an outer periphery of the source section of the reaction vessel 20, and a growth section heater 22 is provided on an outer periphery of the growth section of the reaction vessel 20. A chlorine-based gas supply tube 4 is connected to the gas supply port of the source vessel 1 installed in the source section of the reaction vessel 20 so as to pass through the side wall of the reaction vessel 20. Further, a metal chloride gas exhaust tube 5 is connected to the gas exhaust port of the source vessel 1, and the metal chloride gas exhaust tube 5 is disposed facing the substrate 25 of the growth section. The reaction vessel includes a NH₃ gas supply tube 23 for supplying NH₃-containing gas G3 including NH₃ gas (ammonia gas), and a doping source gas supply tube 24 for supplying doping source-containing gas G4 containing doping source gas, in the reaction vessel 20 in such a manner as passing through the side wall of the reaction vessel 20 in parallel to the metal chloride gas exhaust tube 5. The substrate 25 of the growth section of the reaction vessel 20 is held in a vertical state by a susceptor 26 for example, and the susceptor 26 is rotatably supported by a supporting shaft 27. A chlorine-containing gas supply line, a NH₃-containing gas supply line, and a doping source-containing gas supply line are connected to the chlorine-based gas supply tube 4, the NH₃ gas supply tube 23, and the doping source gas supply tube 24, so that the chlorine-based gas, the NH₃ gas, and the doping source gas are respectively supplied thereto. Further, a gas exhaust tube 28 for exhausting the gas in the reaction vessel 20 is provided on the growth section-side side wall of the reaction vessel 20, and the exhaust line not shown is connected to the gas exhaust tube 28.

The source vessel 1 is heated by the source section heater 21. The metal source M is stored in the source vessel 1. The chlorine-based gas in the chlorine-containing gas G1 supplied from the chlorine-based gas supply tube 4 is brought into contact with the metal source M while flowing through the gas passage P formed by the partition plate 6, and the metal chloride-containing gas G2 containing produced metal chloride gas is sent to the growth section from the metal chloride gas exhaust tube 5. Further, the NH₃ gas and the doping source gas are supplied to the growth section from the NH₃ gas supply tube 23 and the doping source gas supply tube 24 respectively. The metal chloride gas and the NH₃ gas supplied to the substrate 25 of the growth section are reacted, to thereby grow the group III nitride semiconductor crystal on the substrate 25. Further, electroconductive group III nitride semiconductor crystal is grown on the substrate 25 by supplying the doping source gas from the doping source gas supply tube 24.

As described above, the inside of the source vessel 1 is partitioned by the partition plate 6, and the gas passage P is formed in the space S in the upper part of the metal source M so as to continue to the gas exhaust port from the gas supply port, with a narrow passage width W of 5 cm or less, having the bent portions E formed in the middle. Therefore, the metal chloride gas with a stable gas concentration is discharged from the metal chloride gas exhaust tube 5, to thereby obtain the HVPE apparatus having a stable growth speed of the nitride semiconductor crystal grown on the substrate 25. Further, the apparatus for producing metal chloride gas using the source vessel 1 is capable of changing the concentration of the produced metal chloride gas with good response efficiency, and therefore the HVPE apparatus capable of suddenly changing the concentration of the metal chloride gas supplied to the substrate 25 can be obtained. Accordingly, it becomes possible to suddenly start or stop the growth of the nitride semiconductor crystal, and suddenly change the growth speed, or form a steep hetero interface, which are difficult by a conventional HVPE apparatus.

### (Nitride Semiconductor Wafer)

A nitride semiconductor wafer according to an embodiment of the present invention is the nitride semiconductor wafer in which a film composed of GaN, AlN, and InN or a mixed crystal of them is formed on the substrate by supplying metal chloride gas and ammonia gas to the substrate. Wherein, at least a carrier concentration in the upper part of the film, is in a range of 4×10¹⁷ to 3×10¹⁹, and a carrier concentration distribution is in a range of ±10% from an average value, and a deviation (standard deviation) σ is within 5%, and a thickness of a low carrier concentration layer on an outermost surface of the film is 60 nm or less, at least in a depth of 60 nm to 1 μm from a surface of the upper part of the film.

The nitride semiconductor wafer according to this embodiment can be realized by using the HVPE apparatus of the present invention represented by the aforementioned embodiment. The thickness of the low carrier concentration layer can be set to 60 nm or less by using the source vessel 1 capable of shorting the transition time from a halt of the supply of the metal chloride gas until the concentration of the metal chloride gas is gradually changed to be fixed (zero). The nitride semiconductor wafer also includes a template in which a GaN thick film is grown on a sapphire substrate for example.

### (Nitride Semiconductor Device)

According to the nitride semiconductor device of the first embodiment of the present invention, a semiconductor device structure composed of a semiconductor layer laminate and an electrode that function as semiconductor function sections, is formed on the nitride semiconductor wafer of this embodiment. According to this nitride semiconductor device, a low carrier concentration layer of the outermost surface of the nitride semiconductor wafer is thin, and therefore a yield rate is remarkably higher than a case of using the nitride semiconductor wafer manufactured by the conventional HVPE apparatus.

### (A Method for Manufacturing a Nitride Semiconductor Freestanding Substrate)

A method for manufacturing a nitride semiconductor freestanding substrate according to a first embodiment of the present invention comprises:

supplying to a substrate, metal chloride gas and ammonia gas produced from an apparatus for producing metal chloride gas, using the apparatus for producing metal chloride gas according to the aforementioned embodiment;

growing a nitride semiconductor film such as GaN on the substrate; and

manufacturing a nitride semiconductor freestanding substrate from the nitride semiconductor film.

According to the method for manufacturing the nitride semiconductor freestanding substrate according to this embodiment, the growth speed can be stably maintained by using the apparatus for producing metal chloride gas according to the aforementioned embodiment, and the time required for manufacturing the nitride semiconductor freestanding substrate can be drastically shortened.

### EXAMPLES

Examples of the present invention will be described in detail hereafter. However, the present invention is not limited to these examples.

### Example 1

In example 1, in the HVPE apparatus with a structure shown in FIG. 2, the change of the GaCl concentration in the growth section of the HVPE apparatus was examined, when setting on/off the introduction of the HCl gas into the source vessel in a case that the structure of the source vessel containing Ga was variously changed as shown in FIG. 3A to FIG. 3F. The GaCl concentration was measured by inserting a quartz tube into the growth section in the reaction vessel of the HVPE apparatus from a downstream side, and sucking the gas of the growth section from the quartz tube to outside of the HVPE apparatus, then introducing a part of the gas to a quadrupole mass spectrometer via a pinhole, and measuring a signal intensity caused by the GaCl gas.

Source vessels 1a to 1f shown in FIG. 3A to FIG. 3F used in example 1, are rectangular paralleletubed vessels similarly to the source vessel 1 of FIG. 1, wherein a horizontal length from the gas supply port 2 to the gas exhaust port 3 is 20 cm, a horizontal width vertical thereto is 10 cm, and a height is 5 cm. Ga melt was poured into these source vessels 1a to 1f in a depth range of 1 to 3 cm.

The source vessel 1a of FIG. 3A is in a state similar to a conventional structure in which there is no partition plate in the source vessel 1a. Further, various partition plates are provided in the source vessels shown in FIG. 3B to FIG. 3F. The source vessel 1b of FIG. 3B shows a case that four partition plates 11 with a length of 1.5 cm are installed from the ceiling wall to the bottom wall, between the gas supply port 2 and the gas exhaust port 3. The Ga melt is poured into the source vessel 1b in a depth range of 1 to 3 cm, and therefore as shown in FIG. 4 which is a side cross-sectional view of the source vessel 1b, there is a space of 0.5 to 2.5 cm between lower ends of the partition plates 11 and a liquid surface of the Ga melt corresponding to the depth of the Ga melt, so that the gas flows through this space.

Further, similarly to the source vessel 1 of FIG. 1, the partition plates 6 from the ceiling wall to the vicinity of the bottom wall are installed in various forms, in the source vessels 1c to 1f shown in FIG. 3C to FIG. 3F. Similarly to the source vessel 1 of FIG. 1, the partition plates 6 are provided in the source vessel 1c, 1e, and 1f, for divining a space between the gas supply port 2 and the gas exhaust port 3 at equal intervals in parallel to the side wall where the gas supply port 2 and the gas exhaust port 3 are formed. The space of 2 cm is formed between the partition walls 6 and the side wall in the bent portion of the gas passage in the source vessels 1c, 1e, and 1f. One partition wall 6 is formed in the source vessel 1c, and two partitions walls 6 are formed in the source vessel 1e, and five partition walls are formed in the source vessel 1f respectively, and the passage width W of the gas passage becomes narrower in an order of the source vessel 1c, the source vessel 1e, and the source vessel 1f.

Further, the source vessel 1d of FIG. 3D shows a case that the partition plate 6 is provided, extending on a diagonal line from a corner of the gas exhaust port 3 side to a corner of the gas supply port 2 side.

In the HVPE apparatus with a structure shown in FIG. 2, mixed gas of hydrogen and nitrogen was flowed from an upstream side (left side of the figure) through a group V line (NH₃ gas supply tube 23) and a doping line (a doping source gas supply tube 24), and HCl and a mixed gas of hydrogen and nitrogen was flowed through a group III line (chlorine-based gas supply tube 4). A total flow rate of the group III line was fixed to 800 sccm.

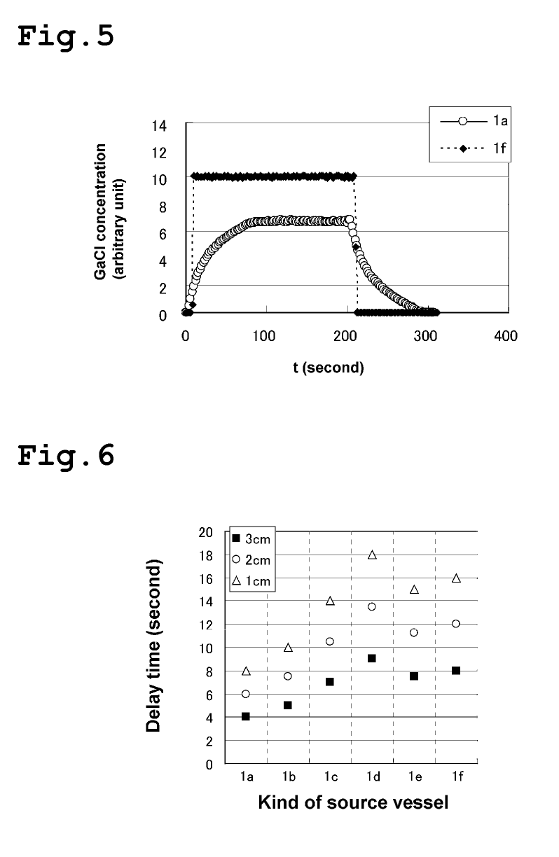

The source vessels 1a to 1f were used, and 800 sccm of the mixed gas of hydrogen and nitrogen only was supplied to the III line before time t=0 (second), and introduction of HCl-containing gas (the flow rate of HCl=50 sccm, and the flow rate of the mixed gas of hydrogen and nitrogen=750 sccm) was started to the group III line at time t=0 (second), then the introduction of the HCl gas was ended at time t=200 (seconds), and 800 sccm of the mixed gas of hydrogen and nitrogen only was flowed again. FIG. 5 shows the change of the signal intensity (GaCl concentration) caused by GaCl in a case of using the source vessel 1a and the source vessel 1f.

As shown in FIG. 5, in each case of the source vessel 1a and the source vessel 1f, there is a slight delay (delay time) from setting on or off of the supply of HCl until the GaCl concentration is changed. Further, a certain degree of time (transition time) is required from start of the change of the GaCl concentration until the GaCl concentration is fixed (maximum concentration or zero concentration). Further, the GaCl concentration (GaCl concentration during stable time) which is fixed after start of the supply of HCl, is different depending on the kind of the source vessel containing Ga.

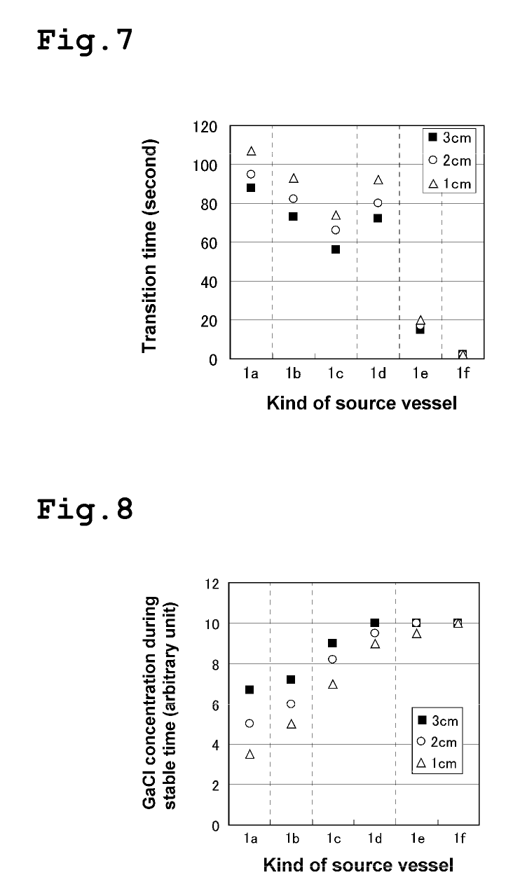

FIG. 6 shows a relation between the source vessels 1a to 1f and the delay time, in a case that depths of Ga in the source vessels are 1, 2, 3 cm. FIG. 7 shows a relation between the source vessels 1a to 1f and the transition time in a case that the depths of Ga in the source vessels are 1, 2, 3 cm. Also, FIG. 8 shows a relation between the source vessels 1a to 1f and the GaCl concentration during stable time (maximum concentration). Further, these relations are collectively shown in table 1.

TABLE 1

| | Depths of Ga | | | | | | | | |
|---|---|---|---|---|---|---|---|---|---|
| | 3 cm | | | 2 cm | | | 1 cm | | |
| | | | Concentration | | | Concentration | | | Concentration |
| Kind of | Delay | Transition | of maximum | Delay | Transition | of maximum | Delay | Transition | of maximum |
| source | time | time | GaCl | time | time | GaCl | time | time | GaCl |
| vessel | (second) | (second) | (arbitrary unit) | (second) | (second) | (arbitrary unit) | (second) | (second) | (arbitrary unit) |
| 1a | 4.0 | 88 | 6.7 | 6.0 | 95 | 5 | 8.0 | 107 | 3.5 |
| 1b | 5.0 | 73 | 7.2 | 7.5 | 82 | 6 | 10.0 | 93 | 5 |
| 1c | 7.0 | 56 | 9 | 10.5 | 66 | 8.2 | 14.0 | 74 | 7 |
| 1d | 9.0 | 72 | 10 | 13.5 | 80 | 9.5 | 18.0 | 92 | 9 |
| 1e | 7.5 | 15 | 10 | 11.3 | 17 | 10 | 15.0 | 20 | 9.5 |
| 1f | 8.0 | 2 | 10 | 12.0 | 2 | 10 | 16.0 | 2 | 10 |

First, explanation will be given for a case that the Ga depth is 3 cm. In a case of the source vessel of a conventional structure without partition plates, the delay time was 4 seconds, the transition time was 88 seconds, and GaCl concentration at the maximum concentration time (during stable time) was 6.7. Note that a value of the GaCl concentration was set to 10 in a case that introduced HCl was entirely changed to GaCl. In a case of the source vessel 1a in which the GaCl concentration at the maximum concentration time was 6.7, only 67% of the introduced HCl was changed to GaCl even at a maximum time.

In a case of the source vessel 1b using the partition wall 11 opened on a downward-opened form that does not reach the Ga melt and in a case of the source vessel 1c in which one partition plate 6 closed in a downward-closed form inserted into the Ga melt, the delay time was slightly extended (5 seconds, 7 seconds respectively), and the transition time was slightly reduced (73 seconds and 56 seconds respectively). Further, the GaCl concentration at a maximum concentration time (during stable time) was increased (7.2, 9 respectively).

Meanwhile, in a case of the source vessel 1d in which a diagonally disposed partition plate 6 closed in a downward-closed form was installed, the delay time was 9 seconds, the transition time was 72 seconds, and the GaCl concentration at the maximum concentration time (during stable time) was 10 on the assumption that the introduced HCl was entirely changed to GaCl.

In a case of the source vessels 1e, 1f in which inside of the source vessel is finely divided into the gas passages by increasing the number of partition plates 6 more than the case of the source vessel 1c, the delay time was about 8 seconds in any one of the source vessels. However, the transition time was dramatically shortened to 15 seconds and 2 seconds respectively. Further, the GaCl concentration at the maximum concentration time was 10 in any one of the source vessels.

When the Ga depth in the source vessel was reduced, the delay time was increased in any one of the source vessels. The delay time in this case was a value substantially proportional to the height of the space (namely, the volume of the space) on the Ga liquid surface in the source vessel. In the source vessels 1a to 1d, if the Ga depth was smaller, the transition time was increased, and the GaCl concentration during stable time (maximum concentration time) was reduced. Meanwhile, in a case of the source vessels 1e and 1f with inside of the source vessel divided into thin gas passages, the change of the GaCl concentration at the transition time and the stable time (maximum concentration time) was small, or the GaCl concentration was not changed at all, even if the Ga depth is changed.

From table 1 and FIG. 6 to FIG. 8, it is found that the partition plates 6 closed in a downward-closed form are increased, to thereby make the passage width W thin (narrow) of the gas passages for passing the gas, and the thinner (narrower) the passage width W is, the shorter the transition time is, and the GaCl concentration during stable time is increased, excluding a case that extremely large standstill or stagnation exists like the source vessel 1d. Further, as the passage width W of the gas passage becomes thinner, the Ga depth is reduced, and when the Ga depth is reduced, increase of the transition time and reduction of the GaCl concentration during stable time are likely to be suppressed.

From the above result, it is found that the transition time is long, when the gas flows through a relatively free wide space in the source vessel like the source vessel 1a and the source vessel 1b, or when the large standstill or stagnation exists in the source vessel like the source vessel 1d.

It is also found that the transition time is decreased and the GaCl concentration during stable time is increased, and further an influence of the Ga depth on the transition time and the GaCl concentration during stable time can be suppressed, when the partition plate closed in a downward-closed form is installed so as to limit the gas passage in the source vessel to one route with approximately no branch in the source vessel like the source vessels 1c, 1e, 1f in particular, and when the passage width of the gas passage is made narrower by increasing the partition plates.

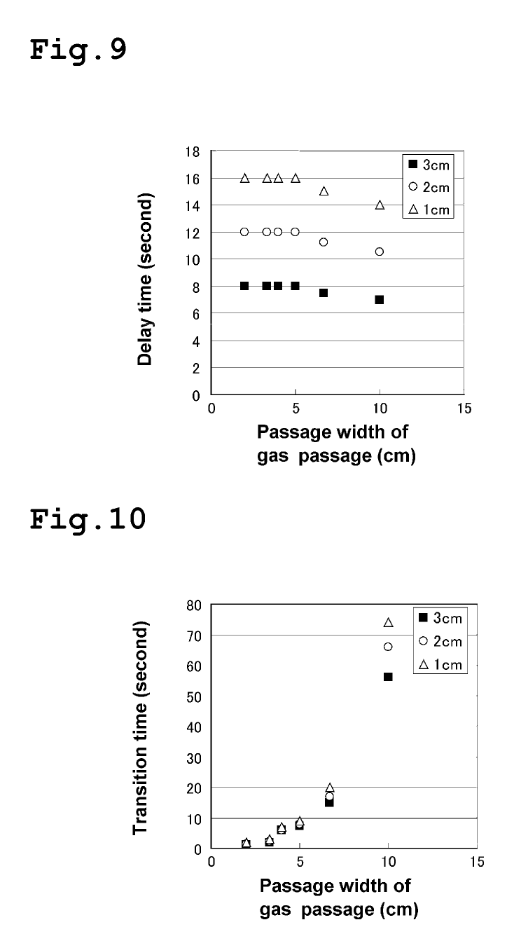

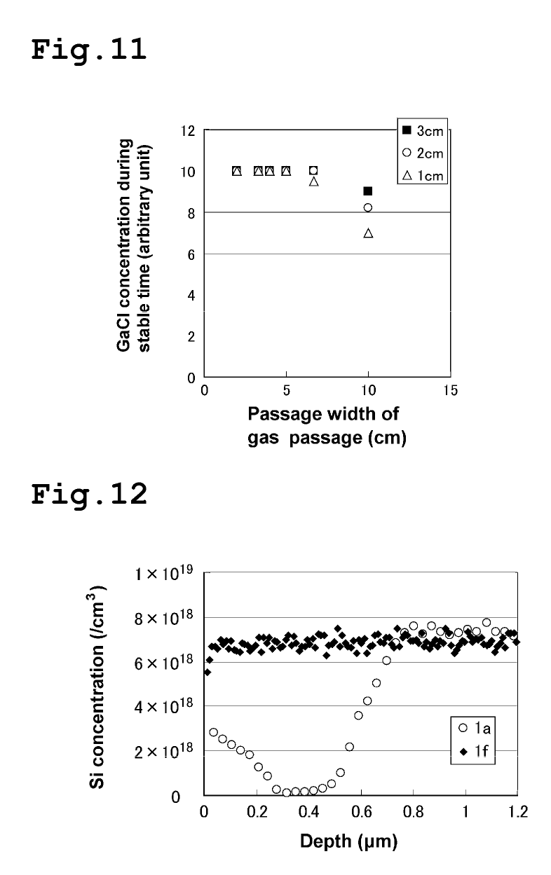

In order to confirm the above concept, similarly to the source vessels 1c, 1e, 1f, by fabricating the source vessel in which the gas passage was limited to one route so as to meander with almost no branch like the source vessels 1c, 1e, 1f, and by changing the number of the partition plates of these source vessels from one to nine, the GaCl concentration was examined in a case that the passage width W of the gas passage was set to 10 cm to 2 cm. Results are shown in table 2 and FIG. 9 to FIG. 11. FIG. 9 shows a relation between the passage width of the gas passage and the delay time, FIG. 10 shows a relation between the passage width of the gas passage and the transition time, and FIG. 11 shows a relation between the passage width of the gas passage and the GaCl concentration during stable time (maximum concentration time) respectively, wherein the Ga depth in the source vessel is set to 1, 2, 3 cm. The source vessel with the passage width of 10 cm is the case of the aforementioned source vessel 1c, and the source vessel with the passage width of 6.7 cm is the case of the aforementioned source vessel 1e, and the source vessel with the passage width of 3.3 cm is the case of the aforementioned source vessel 1f.

From the table 2 and FIG. 9 to FIG. 11, it was confirmed that the transition time was long in a case that the width of the gas passage was large, and the GaCl concentration was low during stable time (maximum concentration time), and there was a large influence of the Ga depth on the transition time and the GaCl concentration. Further, if the width of the gas passage was made narrower, the transition time became shorter, and the GaCl concentration during stable time (maximum concentration time) was increased, and it was also confirmed that there was a small influence of the Ga depth on the transition time and the GaCl concentration.

TABLE 2

| | Ga depth | | | | | | | | | |
|---|---|---|---|---|---|---|---|---|---|---|
| | 3 cm | | | 2 cm | | | 1 cm | | | |
| Passage | | | Maximum | | | Maximum | | | Maximum | |
| width of | Delay | Transition | GaCl | Delay | Transition | GaCl | Delay | Transition | GaCl | |
| gas passage | time | time | concentration | time | time | concentration | time | time | concentration | |
| (cm) | (second) | (second) | (arbitrary unit) | (second) | (second) | (arbitrary unit) | (second) | (second) | (arbitrary unit) | NB |
| 10 | 7.0 | 56 | 9 | 10.5 | 66 | 8.2 | 14.6 | 74 | 7 | 1c |
| 6.7 | 7.5 | 15 | 10 | 11.3 | 17 | 10 | 15.0 | 20 | 9.5 | 1e |
| 5 | 8.0 | 7.2 | 10 | 12.0 | 8 | 10 | 16.0 | 9 | 10 | |
| 4 | 8.0 | 5.8 | 10 | 12.0 | 6 | 10 | 16.0 | 7 | 10 | |
| 3.3 | 8.0 | 2 | 10 | 12.0 | 2.2 | 10 | 16.0 | 3 | 10 | 1f |
| 2 | 8.0 | 1.2 | 10 | 12.0 | 1.5 | 10 | 16.0 | 2 | 10 | |

Particularly, in a case that the passage width W of the gas passage was 5 cm or less (the number of the partition plates was three or more), the transition time was only 9 seconds and the GaCl concentration during stable time was 10 when HCl was completely changed to GaCl, even in a case that the Ga depth was 1 cm and small, namely, even when the space S was largest.

Meanwhile, it was found that the delay time tended to be increased in a case of a small passage width W of the gas passage. This is an effect of cutting-off a route of the gas by a newly added partition plate, which is the route through which the gas flows by shortcutting the inside of the source vessel, and which exists in a case of a large passage width of the gas passage. If the passage width of the gas passage is made narrower, the delay time is prolonged. It appears that the prolonged delay time involves a practical problem. However, as shown in FIG. 9, the delay time can be estimated from the Ga depth during growth as shown in FIG. 9, and therefore no practical serious problem occurs, provided that the delay time is stable.

From the above-described result, it seems to be important that the passage width of the gas passage vertical to a flowing direction is set to 5 cm or less, for shortening the transition time and setting the GaCl concentration during stable time to 10 (conversion of 100%), and further suppressing the influence of the Ga depth on the transition time and the GaCl concentration.

When the GaCl concentration during stable time is 10, the influence of the Ga depth on the GaCl concentration becomes small, and this is because conversion efficiency of HCl to GaCl is 100%. If the Ga depth is changed, the flow of the gas is also changed in the source vessel. Therefore, when the conversion efficiency is 100% or less, the Ga depth has an influence on the GaCl concentration during stable time. However, under a circumstance of the conversion efficiency of 100%, the change of the Ga depth has no influence on the GaCl concentration, because the conversion efficiency of 100% or more is improbable.

With a structure of the source vessel not using the partition plates similar to those of FIG. 3A, the width vertical to the flowing direction of the gas in the source vessel can be thin and long to be 5 cm or less. Such a source vessel was actually fabricated, with a length from the gas supply port to the gas exhaust port set to be large to 60 cm, to thereby conduct an experiment similar to the aforementioned experiment. However, in this case, although the transition time was shortened to 7 to 10 seconds as estimated, the GaCl concentration during stable time was remained to be about 8.5 even in a best state. This result shows that the bent portions of the gas passage that exist in the source vessels 1c, 1e, 1f of FIG. 3 contribute considerably to the GaCl concentration.

Namely, a fast gas flow is generated in the source vessel by flowing the gas through the passage with a narrow passage width of 5 cm or less. Further, when the fast gas flow passes through the bent portions, a large disturbance of the gas flow occurs, to thereby promote a reaction between HCl and metal Ga, to thereby suppress the increase of the GaCl concentration during stable time, and the influence of the Ga depth on the GaCl concentration. Further, the source vessel with the passage width 5 cm corresponds to a case that the number of the partition plates is 3, and therefore it can be said that the number of the bent portions of the gas passage is preferably 3 or more.

In short, the aforementioned result is that in order to shorten the transition time and set the GaCl concentration during stable time to 10 (conversion of 100%), and further in order to suppress the influence of the Ga depth in the source vessel on the transition time and the GaCl concentration during stable time, it is effective means to limit the gas passage in the source vessel to one route with almost no branch, and set the passage width of the gas passage vertical to the flowing direction to 5 cm or less, and provide bent portions at three places or more on the gas passage.

### Example 2

Next, the experiment similar to the experiment of example 1 was conducted by changing a total flow rate of the gas introduced into the source vessel from 100 to 2000 sccm. In this case, added HCl was fixed to 50 sccm, and the total flow rate was adjusted by the flow rate of the mixed gas of hydrogen and nitrogen.

When the total flow rate was 100 sccm or more and less than 1300 sccm, the result similar to the result of example 1 was obtained. When the total flow rate was 1300 sccm or more, the result similar to the result of example 1 was obtained regarding the transition time. However, the GaCl concentration during stable time was decreased more than the case of example 1, and only about 90% of the conversion efficiency from HCl to GaCl could be obtained even in a best case.

When the total flow rate was set to 1300 sccm or more, the time required for residence of the gas inside of the source vessel, which is introduced into the source vessel (residence time) was extremely short to less than 5 seconds by calculation. From this result, it is found that when the total flow rate to the source vessel is excessively large, the residence time becomes short, and the gas goes out before a complete reaction of the introduced HCl occurs, and therefore the conversion efficiency from HCl to GaCl is decreased.

### Example 3

Next, the experiment similar to the experiment of example 2 was conducted by changing a size of the source vessel.

In a case of a large size of the source vessel, the result similar to the result of example 1 was obtained, when the residence time of the gas was 5 seconds or more even if the total flow rate of the mixed gas was 1300 sccm or more. However, in a case of a small size of the source vessel and in a case of less than 5 seconds of the residence time of the gas, the GaCl concentration during stable time was decreased. It appears that similarly to the example 2, this is because the introduced HCl can't be completely changed to GaCl in a case of a short residence time of the gas in the source vessel.

The results of the example 2 and the example 3 show that an optimal application range is defined when the apparatus for producing metal chloride gas according to the present invention is used. Namely, in a case of an excessively large gas flow rate to the source vessel and an excessively small size of the source vessel, the apparatus for producing metal chloride gas according to the present invention is not suitable. However, the apparatus for producing metal chloride gas according to the present invention is suitable, provided that the gas flow rate and the size of the source vessel are determined, so that the residence time of the gas in the source vessel is 5 seconds or more.

### Example 4

Next, a template was fabricated by sequentially laminating a GaN buffer layer, an undoped GaN layer, and an n-type GaN layer on the substrate, using the HVPE apparatus with a structure shown in FIG. 2 including the source vessels 1a to 1f having various forms shown in FIG. 3 used in example 1.

A sapphire substrate with a diameter of 2 to 6 inches with a surface tilted by 0.3 degrees in A-axis direction from C-plane, was used as the substrate. The sapphire substrate was introduced to the HVPE apparatus, and the temperature of the source vessel was set to 850° C. and the temperature of the growth section was set to 1100° C., to thereby apply hydrogen cleaning to the substrate. Thereafter, the temperature of the growth section was set to 600° C., to thereby grow the GaN buffer layer by 30 nm, and next the temperature of the growth section was set to 1100° C. to thereby grow the undoped GaN layer by 6 μm and the n-type GaN layer by 2 μm. Thus, the template was completed.

In growing the GaN buffer layer, 10 sccm of HCl was flowed to the group III line, and 790 sccm of the mixed gas of hydrogen and nitrogen was flowed thereto, and 1 slm of nitrogen gas was flowed to the doping line, and 1 slm of NH₃ and 2 slm of the mixed gas of hydrogen and nitrogen were flowed to the group V line. Thus, the undoped GaN buffer layer was grown at a growth speed of 200 nm/min.

Meanwhile, in the growth at 1100° C., 50 sccm of HCl was flowed to the group III line, and 750 sccm of the mixed gas of hydrogen and nitrogen was flowed thereto, and 1 slm of nitrogen gas was flowed to the doping line during growth of the undoped GaN layer, and 1 slm in total of dichlorosilane and 150 sccm of HC and nitrogen carrier gas was flowed thereto during growth of the n-type GaN layer, and 1 slm of NH₃ and the mixed gas of hydrogen and nitrogen were flowed to the group V line. Thus, the GaN layer was grown at a growth speed of 1 μm/min.

Further, the growth experiment was conducted in consideration of the delay time which was examined by example 1. Namely, in the end of the growth of the n-type GaN layer, first HCl gas was set-off, and thereafter dichlorosilane was also set-off after elapse of the delay time which was measured in advance. Thus, the undoped layer caused by delay time was refrained from growing. However, in this case as well, GaCl is supplied to a growth region in the transition time, and therefore the undoped layer is grown caused by the supply of GaCl, and therefore a low Si-doped layer with a thickness corresponding to the transition time is formed on the surface of the obtained template.

The GaN film of the template obtained by growth, had a flat surface and a dislocation density of about 0.5 to 8×10⁸/cm². However, a Si concentration distribution in the vicinity of the surface of the GaN film was different, depending on a difference of the source vessels. FIG. 12 shows a result of examining by SIMS an impurity (Si) concentration distribution in the vicinity of the GaN surface of the template grown using the source vessels 1a and 1f shown in FIG. 3A and FIG. 3F. Each case shows a constant Si concentration of about 7×10¹⁸/cm³ at a position far from the surface of a crystal. However, in a case of using the source vessel 1a with no partition plate at all as shown in FIG. 3A, the Si concentration is decreased in a range extending by about 700 nm from the surface of the GaN film, and the Si concentration was decreased to about 1×10¹⁷/cm³ at a position of a lowest Si concentration. Meanwhile, in a case of using the source vessel if of FIG. 3F, the thickness where the Si concentration was decreased on the surface of the GaN film was only 17 nm, and a minimum value of the carrier concentration was about 5.5×10¹⁸/cm³, and the decrease of the Si concentration was small.

In this example, average carrier concentration was 7.0×10¹⁸/cm³ in a deeper place than 17 nm, and the carrier concentration was within ±10% from an average value of the carrier concentration. Further, deviation (standard deviation) σ was calculated, and it was found that the deviation could be controlled within 5%.

Next, a target carrier concentration was changed to 4×10¹⁷/cm³ to 3×10¹⁹/cm³, and samples are repeatedly fabricated. Then, in all samples, the target carrier concentration (average to within ±10%) and the deviation σ of the carrier concentration could be controlled to 5% or less. When an amount of supplied Si source (dichlorosilane) was changed and Si source concentration during vapor phase epitaxy was changed, the carrier concentration could be stably adjusted corresponding to a change amount of the source, even if the carrier concentration in the target GaN film was set to 17-th power to 19-th power. Further, since the transition time could be adjusted and controlled, the thickness of the low Si doped layer on the surface could be controlled.

### Example 5-1

Next, blue LED element was fabricated as a nitride semiconductor device, using the template having a thin low Si concentration layer on the outermost surface which was fabricated in example 4.

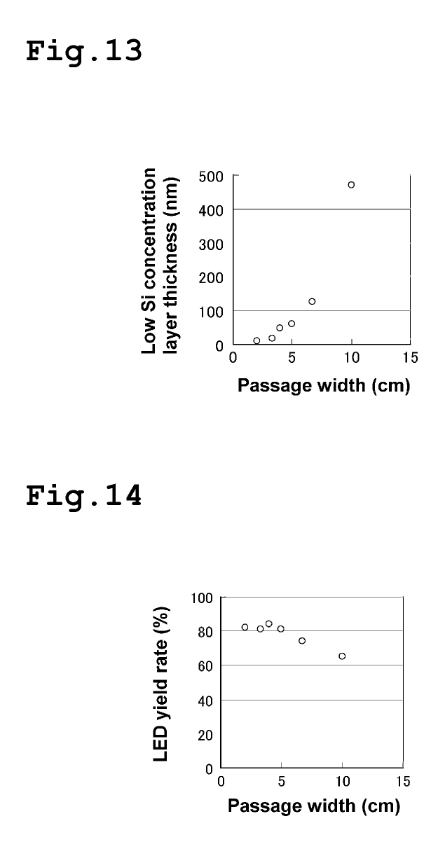

Prior to fabricating the LED element, first, a similar experiment was conducted to the template fabricated using the source vessel with the passage width of the gas passage shown in table 2 changed in a range of 2 to 10 cm. The result thereof is shown in FIG. 13. As shown in FIG. 13, it was confirmed that the thickness of the low Si concentration layer could be decreased, with a decrease of the passage width of the gas passage. Simultaneously, the lowest Si concentration in the low Si concentration layer was also increased, with a decrease of the thickness of the low Si concentration layer.

The thickness of the low Si concentration layer and the lowest concentration of Si, were respectively 470 nm and 8.4×10¹⁷/cm³ in the source vessel 1c with the passage width of 10 cm, 130 nm and 1.2×10¹⁸/cm³ in the source vessel 1e with the passage width of 6.7 cm, 60 nm and 4.0×10¹⁸/cm³ in the source vessel with the passage width of 5 cm, 48 nm and 4.7×10¹⁸/cm³ in the source vessel with the passage width of 4 cm, 17 nm and 5.5×10¹⁸/cm³ in the source vessel if with the passage width of 3.3 cm, and 10 nm and 6.0×10¹⁸/cm³ in the source vessel with the passage width of 2 cm.

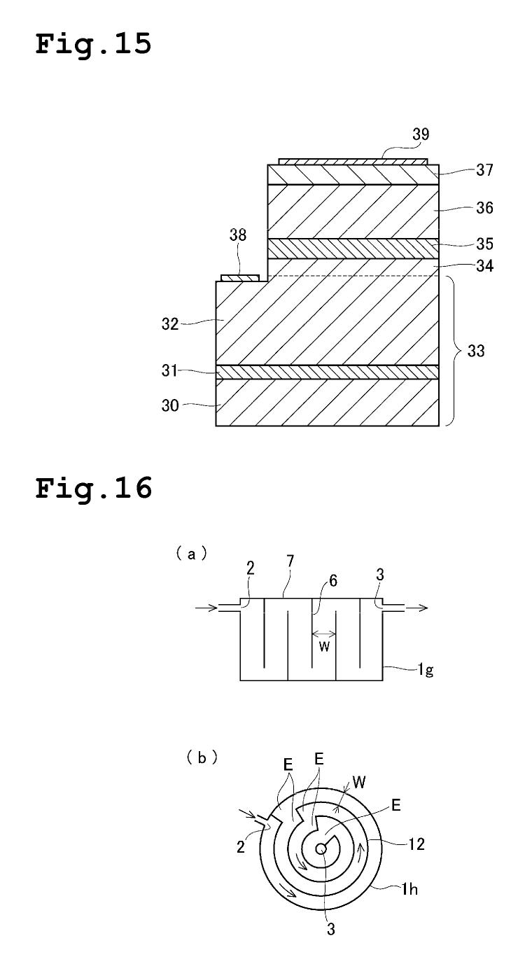

Next, the template fabricated in example 4 was installed on the MOVPE apparatus using the source vessel with the passage width of the gas passage set to 2 to 10 cm, and as shown in FIG. 15, a semiconductor layer with a blue LED structure was grown on a template 33. The template 33 is composed of a lamination of a GaN buffer layer 31, and a GaN layer 32 including the undoped GaN layer of a lower layer, and the n-type GaN layer of an upper layer, on a sapphire substrate 30. A growth procedure of the semiconductor layer with the LED structure using the MOVPE apparatus will be described next.

First, the temperature of the template 3 was raised to 1050° C. while flowing hydrogen, nitrogen, and ammonia, under pressure of 300 Torr. Thereafter, silane gas was introduced to the MOVPE apparatus as n-type dopant together with trimethylgallium (TMG) as a Ga source, to thereby grow n-type GaN layer 34 of 1 μm at a growth speed of 2 μm/h. The carrier concentration of the n-type GaN layer 34 was 5×10¹⁸/cm³.

Subsequently to the growth of the n-type GaN layer 34, 6-pairs of InGaN/GaN multiple quantum well layers 35 (with a thickness of InGaN: 2 nm, and a thickness of GaN: 15 nm) were grown while flowing nitrogen and ammonia gas. Then, a p-type AlGaN layer 36 (Al composition=0.15) and a p-type GaN contact layer 37 (thickness=0.3 μm, carrier concentration=5×10¹⁷/cm³) were grown thereon at a growth speed of 1000° C. Trimethylgallium (TMG) was used as the Ga source, and trimethylindium (TMI) was used as an In source, trimethylaluminum (TMA) was used as an Al source, and dicyclopentadienemagnesium (Cp₂Mg) was used as p-type dopant.

After growth of the aforementioned lamination structure, a substrate temperature was lowered to the vicinity of a room temperature, and the substrate was taken out from the MOVPE apparatus. Thereafter, a semiconductor layer on the obtained substrate surface was partially removed by etching by RIE (Reactive Ion Etching), then apart of the n-type GaN layer 34 (or n-type GaN layer on an upper layer of the GaN layer 32) is exposed, to thereby form n-side electrode 38 of Ti/Al. Further, Ni/Au semi-transparent electrode and a p-electrode pad 39 were formed on the p-type GaN contact layer 37, to thereby fabricate blue LED with a structure shown in FIG. 15.

30 templates were prepared respectively, which were fabricated using each source vessel with different passage widths shown in table 2, and LED was fabricated by growing the MOVPE and forming the electrode on the template, and 10,000 LED elements were selected from an overall surface of the wafer for every 30 templates, to thereby examine the characteristic of the LED element. Emission wavelengths were approximately fixed to 440 to 475 nm in every LED elements. Further, optical output during power supply of 20 mA was 4 to 6 mW, and a drive voltage was between 3.4 to 5V. Out of these LED elements, the LED element with the drive voltage of 3.6V or less at a practical level was regarded as successful, and the element with drive voltage larger than 3.6V was regarded as unsuccessful, and the result of examining the yield rate of the LED in each GaN film is shown in FIG. 14.

In a case of using the source vessel with the width of the gas passage set to 5 cm or less in the LED elements fabricated by the template which was manufactured using each source vessel of table 2, the yield rate was 80% or more. However, the yield rate was decreased to less than 80% if the width of the gas passage was wider than 5 cm. The yield rate was 81% in a case of growing the LED structure on the sapphire substrate similarly to the structure fabricated entirely by the MOVPE method as described above. Therefore in order to obtain the yield rate equivalent to the yield rate of the LED whose semiconductor layer was fabricated entirely by conventional MOVPE, it can be said that the width of the gas passage was set to 5 cm or less, and as shown in FIG. 13, the thickness of the low Si concentration layer on the surface of the template needs to be set to 60 nm or less.

The aforementioned decrease of the yield rate is caused by existence of the low Si concentration layer on the surface of the template and wobbling of an etching depth by RIE performed for forming the n-side electrode 38. As described above, when the width of the gas passage is larger than 5 cm, the thickness of the low carrier concentration layer on the surface of the template was increased, and a minimum carrier concentration of this layer is decreased. The target of the etching depth in the aforementioned etching is 1 μm so as to sufficiently reach the n-type GaN layer 34 of the MOVPE growth. However, in order to improve productivity, the wafers are spread all over a reaction chamber of RIE (diameter of 200 mm), thus generating a difference in the etching speed (1 to 1.6 μm/hr), between a center and an edge of the reaction chamber. Under such an influence, a surface on which the n-side electrode 38 that appears by etching is formed, becomes the low Si concentration layer on the surface of the template in some cases. In a case of a thick low Si concentration layer, the ratio of becoming the low Si concentration layer is increased, regarding the surface on which the n-side electrode 38 that appears by etching is formed, and a contact resistance is increased due to low Si concentration itself of the low Si concentration layer, and the yield rate is reduced.

In order to realize the LED with high yield rate of 80% or more using the template by HVPE method, the apparatus for producing metal chloride gas according to the present invention is inevitable. Namely, by using the template fabricated by the HVPE apparatus including the apparatus for producing metal chloride gas according to the present invention (the template by HVPE method, in which an uppermost part of the template is a film including impurities controlling electroconductivity, and the impurity concentration is approximately fixed from a depth of 60 nm to 1 μm from at least the surface, and the thickness of the low impurity concentration layer on the outermost surface is 60 nm or less), the yield rate equivalent to the yield rate of the LED whose semiconductor layer was formed on the sapphire substrate entirely by the MOVPE method, could be realized for the first time using the template by HVPE method.

### Examples 5-2

Shottky Barrier Diode (SBD) was fabricated as a nitride semiconductor device, using the nitride semiconductor wafer having the thin low carrier concentration layer on the outermost surface. In a case of the SBD, reverse leakage current of diode is increased by excessively increasing the carrier concentration on the outermost surface. Meanwhile, ohmic resistance is increased by excessively decreasing the carrier concentration on the outermost surface. Therefore, the carrier concentration on the outermost surface needs to be strictly controlled. In the SBD, the low carrier concentration layer on the outermost surface is formed in 60 nm or less, and is preferably formed in 20 nm or less. In the present invention, not only the concentration in the GaN film but also the concentration in the vicinity of the surface, can be controlled, and therefore the present invention is suitable for forming the SBD.

FIG. 18 shows the fabricated Shottky Barrier Diode (SBD) 41. The SBD 41 is formed in such a manner that the nitride semiconductor wafer is fabricated, with n-type GaN layer (with a thickness of 5 to 8 μm and carrier concentration of 4×10¹⁷/cm³) 43 formed thereon, using the HVPE apparatus of the present invention, and an ohmic electrode 44 and a shottky electrode 45 are formed on the n-type GaN layer 43 of the nitride semiconductor wafer. In this example, the shottky electrode 45 is formed in the center on the n-type GaN layer 43, and the ohmic electrode 44 is formed on the outer periphery so as to surround the shottky electrode 45. By employing the HVPE apparatus and the manufacturing method of the present invention, the carrier concentration distribution in the n-GaN layer 43 can be controlled within ±10% from the average value of the carrier concentration, and the deviation can be controlled within 5%, and the low carrier concentration layer on the outermost surface can be controlled to 20 nm or less. Thus, SBD with excellent characteristic could be obtained.

### Example 6

The experiment similar to the experiments of examples 4, 5, was conducted by setting the temperature of the source vessel to 700 to 950° C., and the result similar to the results of the examples 4, 5 could be obtained.

When the temperature of the source vessel was less than 700° C., the concentration of GaCl during stable time was decreased, and the growth speed of the GaN layer in the growth section of the HVPE apparatus was also decreased, simultaneously with the decrease of the concentration of GaCl. Further, the dislocation density of the GaN layer was increased. It appears that this is because unreacted HCl is generated due to excessively low temperature of the source vessel. Meanwhile, when the temperature of the source vessel was higher than 950° C., a high value of the GaCl concentration during stable time was maintained. However, dot-shaped abnormal parts are generated on the grown GaN surface with high density, thus not forming the template capable of growing LED. In this case, it appears that since the temperature of the source vessel is high, Ga in a vapor state is also carried to the growth section together with GaCl, to thereby generate Ga droplet on the GaN surface during growth, resulting in generation of the abnormal growth with such a droplet as a nucleus.

### Example 7

Similarly to example 1 to example 4, but by using In instead of Ga, and setting the temperature of the source vessel containing In to 300 to 800° C., and using the produced InCl gas, InN template was fabricated, with the temperature of the growth section set to 500° C., and the result similar to the result of example 4 was obtained.

When the temperature of the source vessel was less than 300° C. and higher than 800° C., similarly to example 6, decrease of the growth speed and increase of the dislocation density, or the dot-shaped abnormal growth was observed.

### Example 8

The experiment similar to the experiment of example 7 was conducted using Cl₂ gas instead of HCl gas. In this case, not only InCl gas but also InCl₃ gas is produced. In this case as well, the result approximately similar to the result of example 7 was obtained.

### Example 9

Similarly to example 1 to example 4, but by using Al instead of Ga, and by heating an Al storage chamber to 400 to 700° C., and using AlCl₃-containing gas produced by introducing HCl-containing gas from the aforementioned entrance, to thereby fabricate an AlN template. In this case, the result similar to the results of example 1 to example 4 was obtained.

When the temperature of the Al storage chamber was lower than 400° C., decrease of the growth speed and increase of the dislocation density were observed similarly to example 6. Further, when the temperature of the Al storage chamber was set to 700° C., AlCl was produced, to thereby cause corrosion of quartz that constitutes a growth apparatus. Therefore, the temperature of the Al storage chamber was set to 700° C. or less.

### Example 10

When the experiment similar to the experiments of the aforementioned examples 1 to 9, was conducted using other inert gas (argon gas, helium, or a mixed gas of them) instead of nitrogen gas, the result similar to the results of examples 1 to 9 was obtained.

### Example 11

A GaN freestanding substrate was fabricated by a method described in the aforementioned patent document 1, using the HVPE apparatus in which the source vessel 1a of FIG. 3A was installed, and using the HVPE apparatus in which any one of the source vessels with the passage width of 5 cm or less according to the examples of the present invention and having three or more bent portions. Namely, the undoped GaN layer was grown on the sapphire substrate, and heat treatment was applied to the substrate with Ti film deposited on the undoped GaN layer in air current in which H₂ and NH₃ were mixed. Thus, the Ti film was turned into TiN film with minute holes formed thereon, and a plurality of voids were formed on the undoped GaN layer. The sapphire substrate was used as a template, having the undoped GaN layer with voids formed thereon, and having the TiN film with minute holes formed thereon, so that the GaN layer was grown thereon as a GaN freestanding substrate.

The GaN layer was grown under a similar condition as the condition of example 4, by introducing HCl by 200 sccm into the source vessel during growth of GaN. Under this condition, the GaN film of several μm was experimentally grown on the sapphire substrate, and the growth speed in this case was 160 μm/hr in the case of using the source vessel 1a of FIG. 3A, and 240μm/hr in the case of using the source vessels of the examples of the present invention.

In the case of using the source vessels of the examples of the present invention, the GaN freestanding substrate of 960 μm was obtained when the growth of 4 hours was carried out under the aforementioned growth condition. This means that a constant growth speed was maintained through the overall growth of the GaN freestanding substrate. Meanwhile, when the source vessel 1a of FIG. 3A was used, the GaN freestanding substrate of 780 μm was obtained by the growth of 6 hours. The average growth speed in this case was 130 μm/hr, and the growth speed was decreased more than the result of the experiment in which the GaN film of several μm was grown. This is because when the source vessel 1a of FIG. 3A without partition plates is used, the growth speed is gradually decreased by consuming Ga during growth of the GaN freestanding substrate for a long time.

Namely, source efficiency can be more improved than conventional and the freestanding substrate can be manufactured at a stable growth speed, by manufacturing the nitride semiconductor freestanding substrate using the apparatus for producing metal chloride gas according to the present invention. Such stability in the growth speed is extremely important for growing n-type, p-type, or semi-insulating GaN freestanding substrates doped with impurity. This is because if the growth speed is changed with a lapse of time, the impurity in the crystal is also changed corresponding to a change rate of the growth speed, and therefore it is not only impossible to manufacture the uniformly doped freestanding substrate but also impossible to obtain a desired doping amount of impurities.

By using the source vessels of the examples of the present invention, for example the change of the growth speed at the time of manufacturing the GaN freestanding substrate with a thickness of 1000 μm, can be suppressed to ±2% or less. Therefore, the GaN freestanding substrate doped with impurity can be manufactured, with ±2% or less of a variation in the depth direction of the impurity concentration.

When the GaN freestanding substrate with a thickness of 1000 μm to 2000 μm was repeatedly fabricated 20 numbers of times, the change of the growth speed during growth of GaN was ±10% or less in a case of using the source vessels according to the examples of the present invention. Further, the variation of the impurity concentration of the GaN substrate (GaN crystal) was ±10% or less, and therefore the GaN freestanding substrate doped with impurity with a deviation within ±10% could be fabricated. Also, by using the HVPE apparatus including the apparatus for producing metal chloride gas according to the present invention with the size of the source vessel changed, the GaN substrate with a thickness exceeding 2000 μm can also be fabricated.

Modified examples of the present invention will be described hereafter.

### Modified Example 1

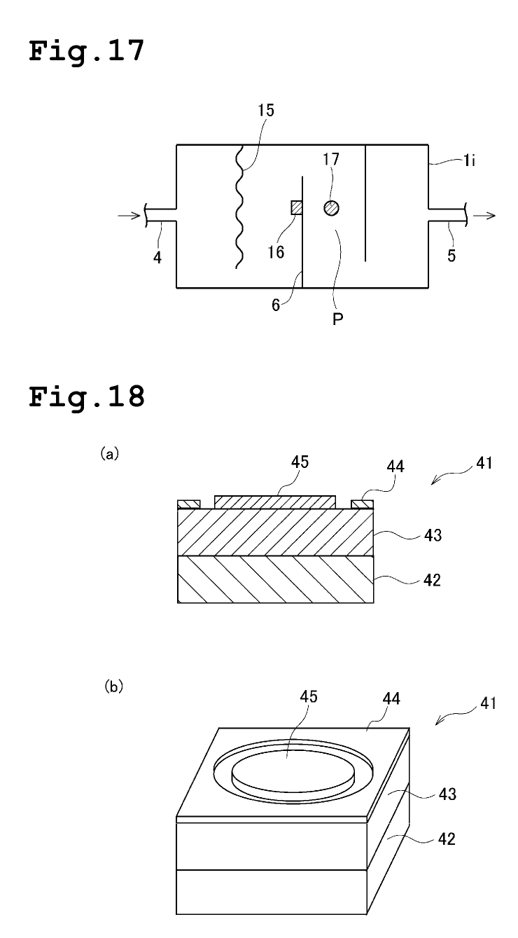

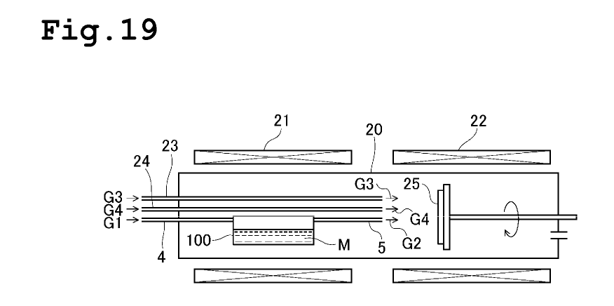

FIG. 16A, FIG. 16B, and FIG. 17 show modified examples of the source vessel used for the apparatus for producing metal chloride gas according to the present invention. A source vessel 1g of FIG. 16A has a structure in which partition plates 6 similar to those of the source vessels 1c, 1e of FIG. 3 are arranged. Wherein the gas supply port 2 and the gas exhaust port 3 are provided at positions closer to one of the side walls 7, and portions such as stagnation or standstill are suppressed to minimum as much as possible around the gas supply port 2 and around the gas exhaust port 3.

Further, a source vessel 1h of FIG. 16B is a circular source vessel, in which the gas passage for flowing the gas in a spiral shape from the gas supply port 2 outside of the source vessel 1h toward the gas exhaust port 3 of the center, is formed by a partition plate 12. The gas passage has bent portions E, at three places or more. In this case, the introduced gas is led out upward or downward from the gas exhaust port 3 in the center. Even in a case of using the source vessel with a shape of the source vessel 1h of FIG. 16B, substantially the same result as the result of the aforementioned examples can be obtained. Namely, this means that the effect of the present invention can be obtained, provided that a requirement of the source vessel according to the present invention is satisfied, even in a case that the source vessel is formed into a circular shape or the other shape.

Further, a source vessel 1i shown in FIG. 17 shows an example of adding a structure of disturbing a gas flow of a gas passage P, to a structure of arranging the partition plates similar to those of the source vessels 1c, 1e, 1f of FIG. 3. Specifically, as shown in FIG. 17, the partition plate dividing the inside of the source vessel may be formed as a corrugated partition plate 15 instead of the flat plate-shaped partition plate 6, or a projection 16 may be provided on the partition plate 6, or a rod member 17 may be provided in the gas passage P.

### Modified Example 2

The nitride semiconductor wafer of the present invention can reduce the thickness of the low Si concentration layer on the outermost surface of the nitride semiconductor film without depending on the substrate for growing a nitride semiconductor to be used, and therefore, it can be applied not only to a template in which the nitride semiconductor is grown on the sapphire substrate, but also to a template in which the GaN film is formed on a heterogeneous substrate excluding the sapphire substrate, such as GaAs substrate, Ga₂O₃ substrate, ZnO substrate, SiC substrate, or Si substrate.

### Modified Example 3

Further, the present invention can also be applied to an object of fabricating a base material for a device by forming the GaN film on the template grown by other method, or on GaN, AlN, InN single crystal substrates, for the same reason as the aforementioned example 2.

### Modified Example 4

The template composed of a mixed crystal of GaN, InN, AlN or the nitride semiconductor film can also be formed by combining a plurality of apparatuses for producing metal chloride gas, according to the aforementioned embodiments or the aforementioned examples of the present invention.

### Modified Example 5

Further, the apparatus for producing metal chloride gas according to the present invention is effective not only to a purpose of use requiring a sudden on/off operation performed to the metal chloride gas, but also to a purpose of use for suddenly increasing/decreasing the concentration of the metal chloride gas.

As an example, in a case of laminating the LED structure on the template of example 4 by HVPE method similarly to example 5-1, a steep hetero interface can be formed, which is impossible by a conventional HVPE method, and therefore LED having characteristics equivalent to the LED grown entirely by MOVPE method, can be realized.

### Modified Example 6

In the template of example 4, an AlN buffer is grown by 20 nm to 100 nm at 1100° C. instead of the GaN buffer grown at 600° C., and undoped GaN and n-type GaN may be formed thereon at 1100° C.

### Modified Example 7

The growth temperature, the gas flow rate, and a plan orientation of the substrate described in the present invention may be suitably changed for a practical purpose of use. For example, in the example 4, although the HVPE growth temperature is set to 1100° C., a practical temperature range may be set to 1000 to 1200° C.

1. An apparatus for producing metal chloride gas, comprising:
a source vessel configured to store a metal source;
a gas supply port provided in the source vessel, and configured to supply chlorine-containing gas containing chlorine-based gas into the source vessel;
a gas exhaust port provided in the source vessel, and configured to discharge metal chloride-containing gas containing metal chloride gas produced by a reaction between the chlorine-based gas contained in the chlorine-containing gas and the metal source, to outside of the source vessel; and
a partition plate configured to form a gas passage continued to the gas exhaust port from the gas supply port by dividing a space in an upper part of the metal source in the source vessel,
wherein the gas passage is formed in one route from the gas supply port to the gas exhaust port, with a horizontal passage width of the gas passage set to 5 cm or less, with bent portions provided on the gas passage.

2. The apparatus for producing metal chloride gas according to claim 1, wherein the bent portions are formed at three places or more on the gas passage.

3. An apparatus for hydride vapor phase epitaxy, comprising the apparatus for producing metal chloride gas according to claim 1.

4. A method for producing metal chloride gas, wherein a residence time of gas flowing through the gas passage from the gas supply port to the gas exhaust port is set to 5 seconds or more, using the apparatus for producing metal chloride gas according to claim 1.

5. A method for producing metal chloride gas according to claim 4, wherein the metal source is Ga, and the chlorine-containing gas is HCl-containing gas, the method comprising:
heating the source vessel to 700° C. to 950° C.; and
discharging GaCl-containing gas, being the metal chlorine-containing gas, from the gas exhaust port.

6. A nitride semiconductor wafer, wherein a film composed of GaN, AlN, InN or a mixed crystal of them is formed on a substrate by supplying metal chloride gas and ammonia gas, and a carrier concentration is in a range of 4×10¹⁷ to 3×10¹⁹ in at least an upper part of the film, and a carrier concentration distribution is in a range of ±10% from an average value of the carrier concentration, and a deviation σ is within 5%, and a thickness of a low carrier concentration layer on an outermost surface of the film is 60 nm or less, in a depth of 60 nm to 1 μm from at least a surface of the upper part of the film.

7. A nitride semiconductor device, wherein a semiconductor device structure is formed on the nitride semiconductor wafer according to claim 6.

8. A wafer for nitride semiconductor light emitting diode,
wherein the film of the nitride semiconductor wafer described in claim 6 includes a n-type nitride semiconductor film formed by a HVPE method, and a nitride semiconductor light emitting structure layer is formed on the n-type nitride semiconductor film by a MOVPE method,
wherein a carrier concentration is in a range of 4×10¹⁸ to 8×10¹⁸ in a depth from 60 nm to 1 μm on an outermost surface side of the n-type nitride semiconductor film.

9. A method for manufacturing a nitride semiconductor freestanding substrate, comprising:
supplying to a substrate, metal chloride gas and ammonia gas produced from an apparatus for producing metal chloride gas, using the apparatus for producing metal chloride gas according to claim 1;
growing a nitride semiconductor film on the substrate; and
manufacturing a nitride semiconductor freestanding substrate from the nitride semiconductor film.

10. A nitride semiconductor crystal with a thickness of 1000 μm or more composed of GaN, AlN, InN or a mixed crystal of them, formed by metal chloride gas and ammonia gas, wherein a variation of an impurity concentration is ±10% or less, and a deviation is within 10% in a thickness direction of the nitride semiconductor crystal.
